(19) United States
(12) Patent Application Publication
(10) Pub. No.: US 2021/0305441 A1
(43) Pub. Date: Sep. 30, 2021

(54) SEMICONDUCTOR DEVICE PACKAGE AND SEMICONDUCTOR PACKAGE ASSEMBLY

(71) Applicant: Advanced Semiconductor Engineering, Inc., Kaohsiung (TW)

(72) Inventors: Wei-Wei LIU, Kaohsiung (TW); Huei-Siang WONG, Kaohsiung (TW)

(73) Assignee: Advanced Semiconductor Engineering, Inc., Kaohsiung (TW)

(21) Appl. No.: 16/836,406

(22) Filed: Mar. 31, 2020

(51) Int. Cl. H01L 31/0216; H01L 31/0232; H01L 27/146

(52) U.S. Cl. CPC H01L 31/02164; H01L 27/14627; H01L 27/14623; H01L 31/0232

(57) ABSTRACT

The present disclosure provides a semiconductor device package. The semiconductor device package includes a substrate including a sensing region and a first transparent layer disposed over the sensing region. The first transparent layer has a first surface facing the sensing region, a second surface opposite to the first surface of the first transparent layer, and a lateral surface extending between the first surface and the second surface of the first transparent layer. The semiconductor device package further includes a first light blocking layer disposed on the first transparent layer. The first light blocking layer defines a plurality of apertures. At least a portion of the first light blocking layer extends over the lateral surface of the first transparent layer. A semiconductor package assembly is also disclosed.

### BACKGROUND

### 1. Technical Field

The present disclosure generally relates to a semiconductor device package a semiconductor package assembly and, in particular, to a semiconductor device package with a collimating structure.

### 2. Description of the Related Art

Optoelectronic devices such as light sensing devices, image sensing devices, or fingerprint recognition devices, are widely used in consumer electronic goods. An optoelectronic device may contain a collimating structure disposed on a sensing region of a die. Because the collimating structure may be composed of material transparent to the environmental light, environmental light may enter the sensing region through at least from a side surface of the collimating structure and deteriorate the resolution of the optoelectronic devices. Such environmental light interference, or light leakage, is to be resolved in order to enhance the resolution of the optoelectronic devices.

### SUMMARY

In one or more embodiments, the present disclosure provides a semiconductor device package. The semiconductor device package includes a substrate including a sensing region and a first transparent layer disposed over the sensing region. The first transparent layer has a first surface facing the sensing region, a second surface opposite to the first surface of the first transparent layer, and a lateral surface extending between the first surface and the second surface of the first transparent layer. The semiconductor device package further includes a first light blocking layer disposed on the first transparent layer. The first light blocking layer defines a plurality of apertures. At least a portion of the first light blocking layer extends over the lateral surface of the first transparent layer.

In one or more embodiments, the present disclosure provides a semiconductor device package. The semiconductor device package includes a micro lens array over a substrate, a transparent layer surrounding the micro lens array, a light blocking layer surrounding the transparent layer, and a bonding region surrounding the light blocking layer.

In one or more embodiments, the present disclosure provides a semiconductor device package. The semiconductor device package includes a substrate having an active surface. The substrate includes a sensing region and a bonding region disposed adjacent to the active surface or the substrate. The semiconductor device package further includes a transparent layer disposed over the sensing region of the first substrate and an opaque layer disposed on the transparent layer. The opaque layer extends over a lateral surface of the first transparent layer. The semiconductor device package further includes a carrier carrying the substrate, the transparent layer, and the opaque layer. The carrier is electrically connected to the substrate.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1 is a cross-sectional view of a semiconductor device package, in accordance with an embodiment of the present disclosure.

FIG. 2 is a top view of a semiconductor device package, in accordance with an embodiment of the present disclosure.

FIG. 3 is a cross-sectional view of a semiconductor device package, in accordance with an embodiment of the present disclosure.

FIG. 4 is a cross-sectional view of a semiconductor device package, in accordance with an embodiment of the present disclosure.

FIG. 5A is a cross-sectional view of a semiconductor device package, in accordance with an embodiment of the present disclosure.

FIG. 5B is a top view of a semiconductor device package, in accordance with an embodiment of the present disclosure.

FIG. 6 is a cross-sectional view of a semiconductor device package, in accordance with an embodiment of the present disclosure.

FIG. 7 is a cross-sectional view of a semiconductor device package, in accordance with an embodiment of the present disclosure.

FIG. 8 is a top view of a semiconductor package assembly, in accordance with an embodiment of the present disclosure.

FIG. 9A and FIG. 9B illustrate various intermediate stages of a method for manufacturing a semiconductor device package in a cross-sectional perspective, in accordance with some embodiments of the present disclosure.

FIG. 10A and FIG. 10B illustrate various intermediate stages of a method for manufacturing a semiconductor device package in a cross-sectional perspective, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. Besides, the present disclosure may repeat reference numerals and/or letters in the various examples. This repetition is for simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

As used herein the term “opaque” may refer to a structure or a layer which does not allow a light within a specific wavelength range, such as a visible light or an invisible light, to pass through, and the term “transparent” may refer to a structure or a layer which allows a light within a specific wavelength range, such as a visible light or an invisible light, to pass through.

As used herein the term “optically-sensitive material” may refer to a material sensitive to a light within a specific wavelength range in an optical curing operation.

An optoelectronic device may contain a collimating structure disposed on a sensing region of a die. The collimating structure may include a plurality of opaque layers and transparent layers stacked in an alternating fashion. The opaque layers define a plurality of apertures for the light to pass through. Light may pass through the apertures, penetrate through the transparent layers, and arrive at the sensing region. However, light (such as environmental light entering from an oblique angle) may leak-in front the edges of the collimating structure, which may cause a decrease in the resolution of the optoelectronic device.

In a comparative embodiment, the length of the collimating structure may be increased to cover more areas of the substrate adjacent to and not overlapping with the sensing region residing on or in the substrate to block undesired environmental light from entering the sensing region. However, such approache may not block the environmental light entering from a large oblique angle and at the same time, increase the package size due to the fact that no electrical connection elements, such as a conductive pad or bonding pad, may be disposed in the areas of the substrate covered by the extended collimating structure. For example, the boundary of the sensing region may be spaced from the electrical connection element surrounding thereto by at least about 300 micrometer (μm). Moreover, the operations to form such extended collimating structure are costly and time consuming.

By comparison, in the present disclosure, the opaque layer extends over the side wall of at least one of the transparent layers, which solves the light leakage problem and also reduces package size.

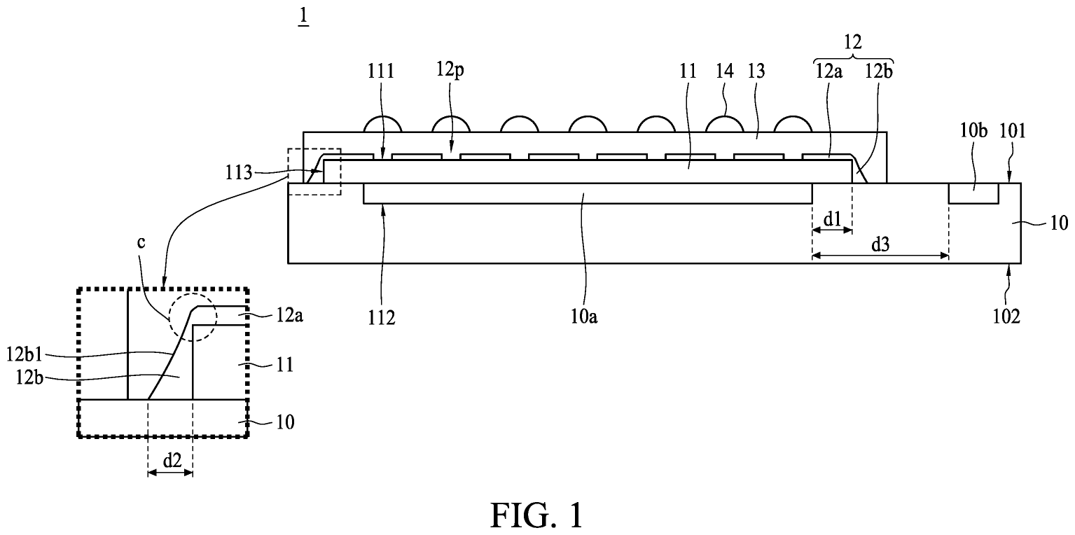

FIG. 1 is a cross-sectional view of a semiconductor device package 1, in accordance with an embodiment of the present disclosure.

The semiconductor device package 1 includes a substrate 10, transparent layers 11 and 13, an opaque layer 12, and a light concentrating layer 14.

In some embodiments, the transparent layers 11 and 13 are optically transparent layers which allow a light within a specific wavelength range to pass through while the opaque layer 12 is a light blocking layer which does not allow the light within the above wavelength range to pass through. In some embodiments, the multi-layered structure (which including the transparent layers 11 and 13, the opaque layer 12, and the light concentrating layer 14) may function as a collimating structure.

The substrate 10 may be, for example, a semiconductor substrate, such as a silicon substrate or another suitable semiconductor substrate. In some embodiments, the substrate 10 may be a semiconductor chip, such as a silicon chip. In some embodiments, the substrate 10 may be a semiconductor wafer, such as a silicon wafer, and includes a plurality of semiconductor chips.

The substrate 10 includes a surface 101 and a surface 102 opposite to the surface 101. In some embodiments, the surface 101 is an active surface and the surface 102 is a passive surface or a backside surface. A sensing region 10a and a bonding region 10b may be in proximity to the surface 101, adjacent to the surface 101, embedded in the surface 101, and/or partially exposed from the surface 101.

In some embodiments, the sensing region 10a may be sensitive to a peak wavelength in visible light spectrum. In some embodiments, the sensing region 10a may be sensitive to a peak wavelength covering non-visible light spectrum. In some embodiments, the sensing region 10a may include a plurality of light-sensing pixels. In some embodiments, the bonding region 10b may be located in a non-optical sensing region. In some embodiments, the bonding region 10b may include a plurality of bonding pads. In some embodiments, a separation (annotated with “d3” in the figures) between an edge of the sensing region 10a and an edge of the bonding region 10b is in a range of from about 50 μm to about 100 μm.

The transparent layer 11 is disposed or supported on the surface 101 of the substrate 10. The transparent layer 11 is disposed over the sensing region 10a of the substrate 10. For example, the transparent layer 11 is at least partially overlapped with the sensing region 10a and is spaced apart from the bonding region 10b. In some embodiments, the transparent layer 11 covers the sensing region 10a.

The transparent layer 11 includes a surface 111 facing away from the substrate 10, a surface 112 opposite to the surface 111, and a surface (such as a lateral surface) 113 extending between the surface 111 and the surface 112. In some embodiments, the shortest distance (annotated with “d1”) between the surface 113 of the transparent layer 11 and an edge of the sensing region 10a is about 50 μm or less. In some embodiments, the shortest distance d1 may be adjusted according to the design requirements. For example, the shortest distance d1 may be 45 μm, 40 μm, 35 μm, or even less as long as the opaque layer 12 on the surface 113 can block undesired environmental light from an oblique angle.

In some embodiments, the surface 111 and the surface 113 of the transparent layer 11 and the surface 101 of the substrate 10 define a stepped feature. In some embodiments, the surface 113 of the transparent layer 11 may be titled. For example, an angle defined by the surface 113 of the transparent layer 11 and the surface 101 of the substrate 10 may be an acute angle.

The opaque layer (which can also be referred to as a light blocking layer) 12 is disposed on the surface 111 and the surface 113 of the transparent layer 11. As shown in FIG. 1, the opaque layer 12 includes a main portion 12a and a tail portion 12b extending from the main portion 12a. The main portion 12a is disposed on the surface 111 of the transparent layer 11 and defines a plurality of apertures 12p. In some embodiments, the apertures 12p of the opaque layer 12 may be aligned with the pixels in the sensing region 10a.

The tail portion 12b extends from an edge of the surface 111 of the transparent layer 11 and to cover the surface 113 of the transparent layer 11. Alternatively stated, the tail portion 12b extends from an edge of the transparent layer 11 toward the bonding region 10b.

In some embodiments, the tail portion 12b is in direct contact with the corners (which is indicated by the circle “c” in the enlarged view of FIG. 1) between the surface 111 and the surface 113 of the transparent layer 11. In some embodiments, the tail portion 12b is in direct contact with the surface 113 of the transparent layer 11. In some embodiments, the tail portion 12b is further in direct contact with a part of the surface 101 of the substrate 10 surrounding the transparent layer 11. For example, the tail portion 12b covers, encapsulates, or surrounds the surface 113 of the transparent layer 11.

In some embodiments, although not shown in the figures, a part of the tail portion 12b that disposed on the corners between the surface 111 and the surface 113 may be thinner than the other parts of the tail portion 12b. For example, the part of the tail portion 12b that disposed on the corners may have the thinnest thickness. In some embodiments, according to various manufacturing conditions, the main portion 12a and the tail portion 12b are disconnected such that a part of the corners of the transparent layer 11 is exposed from the tail portion 12b.

In some embodiments, as shown in the enlarged view, the tail portion 12b includes a tapering profile, which tapers in a direction from the surface 113 of the transparent layer 11 toward the bonding region 10b. For example, a thickness of the tail portion 12b adjacent to the surface 113 is greater than a thickness of the tail portion 12b away from the surface 113 of the transparent layer 11.

For example, the tail portion 12b includes a curved surface (not shown) or a slanted surface 12b1, depending on the material properties and manufacturing parameters of the opaque layer 12. The slanted surface 12b1 is located over the stepped feature defined by the surface 111 and the surface 113 of the transparent layer 11 and the surface 101 of the substrate 10.

In some embodiments, a tail length (annotated with “d2”) of the tail portion 12b is from about 5 μm to about 20 μm. For example, the tail length d2 of the tail portion 12b may be a distance between the surface 113 of the transparent layer 11 and the farthest point of the tail portion 12b from the surface 113 of the transparent layer 11. The tail length d2 of the tail portion 12b may be adjusted according to design requirements.

The transparent layer 13 is disposed on and covers the opaque layer 12. The transparent layer 13 covers and fills the apertures 12p defined by the main portion 12a. The transparent layer 13 covers the tail portion 12b. In some embodiments, the transparent layer 13 is stacked on the tail portion 12b and fully covers the tail portion 12b so that the tail portion 12b can be protected by the transparent layer 13 during descum operation and a thickness and structural integrity of the tail portion 12b can be preserved.

The light concentrating layer 14 is disposed on the transparent layer 13. In some embodiments, the light concentrating layer 14 includes a micro lens array. In some embodiments, the micro lens array may be aligned with the pixels in the sensing region 10a.

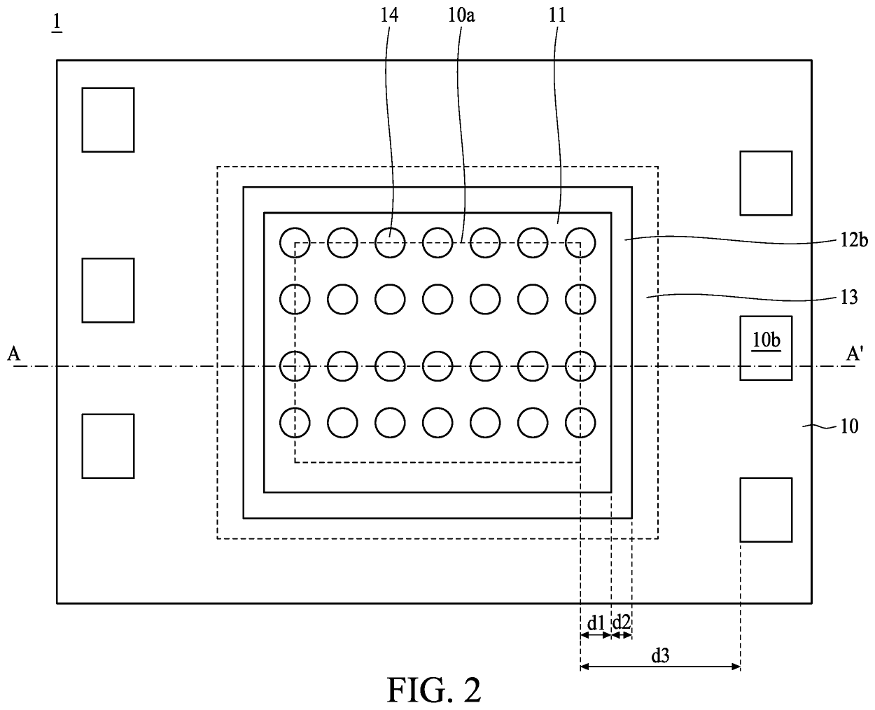

FIG. 2 illustrates a top view of a semiconductor device package 1, in accordance with an embodiment of the present disclosure. The semiconductor device package 1 in FIG. 2 shows a top view of the semiconductor device package 1 in FIG. 1. The semiconductor device package 1 in FIG. 1 may be a cross-sectional view of the semiconductor device package in FIG. 2 taken along line AA′.

As shown in FIG. 2, the sensing region 10a (depicted within the area enclosed by dotted lines) on the substrate 10 is disposed corresponding to the light concentrating layer (or the micro lens array) 14. For example, the sensing region 10a overlaps the light concentrating layer 14. Several bonding regions 10b are located adjacent to and surrounding the sensing region 10a, or the light concentrating layer 14.

The transparent layer 11 surrounds the sensing region 10a and the light concentrating layer 14. The transparent layer 11 covers the sensing region 10a and the light concentrating layer 14.

The tail portion 12b of the opaque layer (such as the opaque layer 12) surrounds the transparent layer 11. For example, the tail portion 12b is adjacent to the edge or periphery of the transparent layer 11. For example, the tail portion 12b abuts the edge or periphery of the transparent layer 11.

As mentioned, the shortest distance d1 between the lateral surface of the transparent layer 11 and an edge of the sensing region 10a is about 50 μm or less. A tail length d2 (or the greatest width) of the tail portion 12b is from about 5 μm to about 20 μm. A separation d3 between an edge of the sensing region 10a and an edge of the bonding region 10b is in a range of from about 50 micrometer (μm) to about 100 μm.

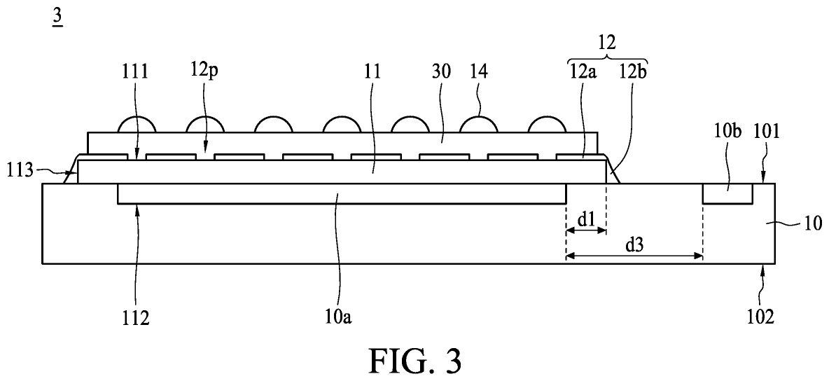

FIG. 3 is a cross-sectional view of a semiconductor device package 3, in accordance with an embodiment of the present disclosure. The semiconductor device package 3 in FIG. 3 is similar to the semiconductor device package 1 in FIG. 1, and the differences therebetween are described below.

The semiconductor device package 3 includes a transparent layer 30 disposed on the main portion 12a of the opaque layer 12. The tail portion 12b of the opaque layer 12 is exposed from the transparent layer 30. In comparison with the semiconductor device package 1 (in which the tail portion 12b of the opaque layer 12 is covered by the transparent layer 13), the package size of the semiconductor device package 3 can be further reduced.

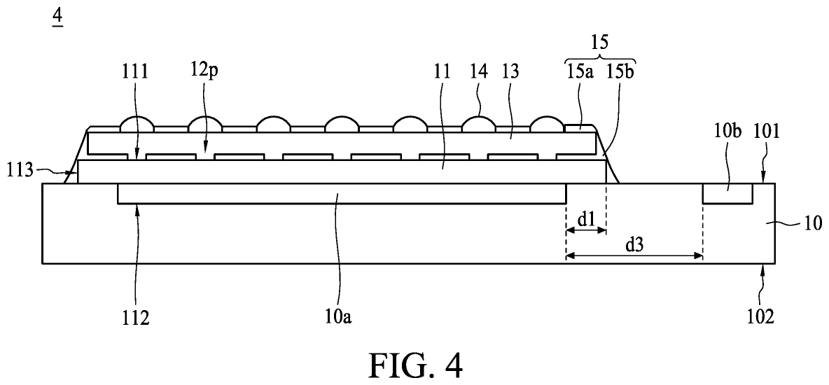

FIG. 4 is a cross-sectional view of a semiconductor device package 4, in accordance with an embodiment of the present disclosure. The semiconductor device package 4 in FIG. 4 is similar to the semiconductor device package 1 in FIG. 1, and the differences therebetween are described below.

The semiconductor device package 4 includes another opaque layer 15 disposed on the transparent layer 13. Similarly, the opaque layer 15 includes a main portion 15a and a tail portion 15b extending from the main portion 15a toward the bonding region 10b. The main portion 15a defines a plurality of apertures. The micro lens array may be disposed corresponding to the apertures. The tail portion 15b covers a lateral surface of the transparent layer 13. In some embodiments, the tail portion 15b is in contact with the tail portion 12b surrounding the transparent layer 11 as labeled in the semiconductor device package 1 of FIG. 1.

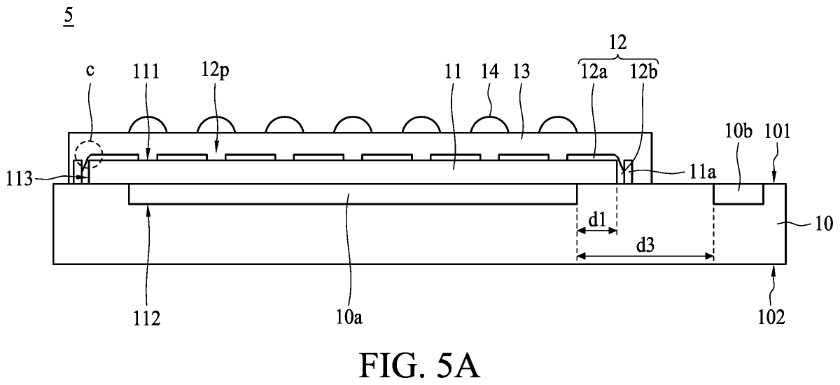

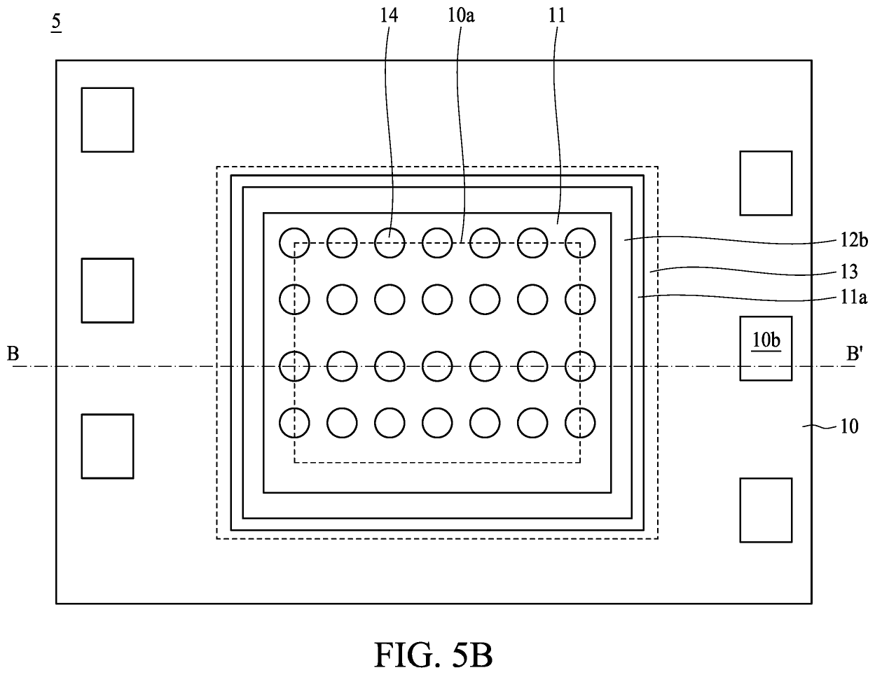

FIG. 5A is a cross-sectional view of a semiconductor device package 5, in accordance with an embodiment of the present disclosure. The semiconductor device package 5 in FIG. 5A is similar to the semiconductor device package 1 in FIG. 1, and the differences therebetween are described below.

The semiconductor device package 5 includes a constraining structure 11a disposed on the surface 101 of the substrate 10. The constraining structure 11a is spaced apart from the transparent layer 11. In some embodiments, the constraining structure 11a is configured to constrain the opaque layer 12. For example, a part of the opaque layer 12 is disposed between the constraining structure 11a and the transparent layer 11. For example, the opaque layer 12 is in contact with the constraining structure 11a. For example, in comparison with the semiconductor device package 1 (in which the constraining structure 11a is omitted), the opaque layer 12 disposed on the corner (which is indicated by the circle “c”) is thicker, and thus the device reliability can be improved.

FIG. 5B illustrates a top view of a semiconductor device package, in accordance with an embodiment of the present disclosure. The semiconductor device package in FIG. 5B is similar to the semiconductor device package 1 in FIG. 2, and the differences therebetween are described below. For example, the semiconductor device package 5 in FIG. 5A may be a cross-sectional view of the semiconductor device package in FIG. 5B taken along line BB′.

As shown in FIG. 5B, the constraining structure 11a surrounds the transparent layer 11. The tail portion 12b of the opaque layer (such as the opaque layer 12) is disposed between the constraining structure 11a and the transparent layer 11. The tail portion 12b of the opaque layer surrounds the transparent layer 11 and is surrounded by the constraining structure 11a. In some embodiments, the tail portion 12b of the opaque layer fills in the space between the constraining structure 11a and the transparent layer 11.

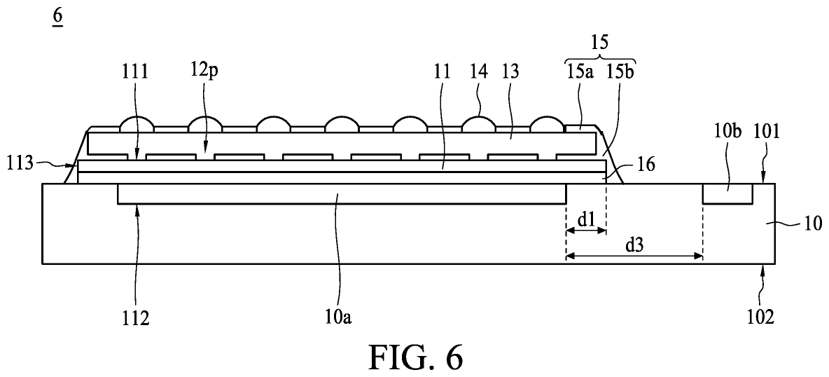

FIG. 6 is a cross-sectional view of a semiconductor device package 6, in accordance with an embodiment of the present disclosure. The semiconductor device package 6 in FIG. 6 is similar to the semiconductor device package 4 in FIG. 4, and the differences therebetween are described below.

The semiconductor device package 6 includes a filter layer 16 disposed between the substrate 10 and the transparent layer 11. In some embodiments, the filter layer 16 is configured to filter out a portion of the light within a specific wavelength range that may be deemed as noise before the received light entering the sensing region 10a.

In some embodiments, the semiconductor device package (such as the semiconductor device packages 1 through 6) according to the present disclosure may incorporate other layers such as a reflecting layer, a conducting layer, or another light-guiding element according to design requirements.

In addition, the semiconductor device package (such as the semiconductor device packages 1 through 6) according to the present disclosure may have any numbers of layer(s) of the transparent layer and the opaque layer according to design requirements, and is not limited to the specific embodiments illustrated in the figures.

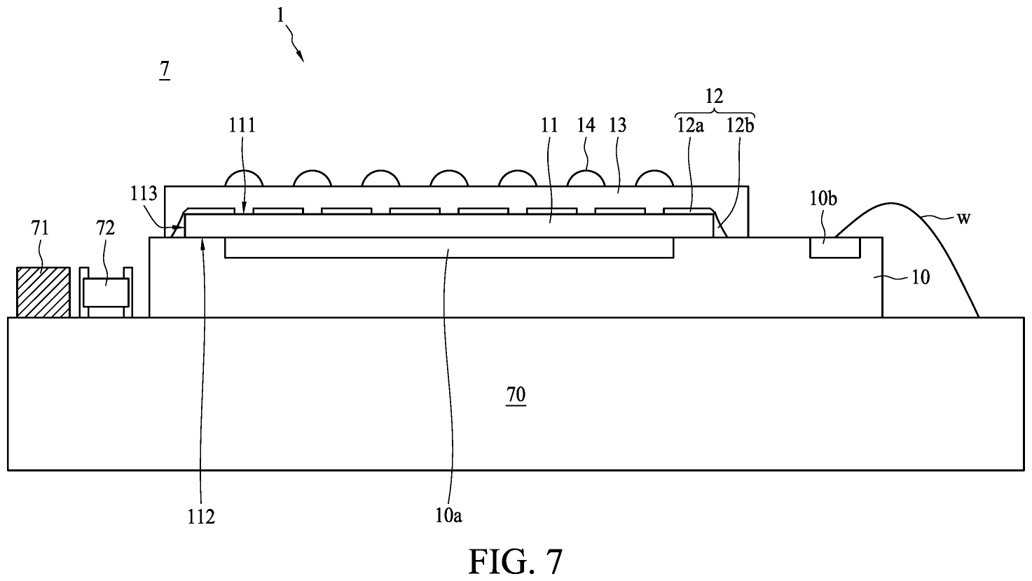

FIG. 7 is a cross-sectional view of a semiconductor device package 7, in accordance with an embodiment of the present disclosure.

The semiconductor device package 7 includes a carrier 70 and a structure (such as the semiconductor device package 1 or the other ones) disposed or carried on the carrier 70. The semiconductor device package 1 is electrically connected to the carrier 70 through a bonding wire w. The bonding wire may be connected between the bonding region 10b and a bonding pad (not shown in the figures) on the surface of the carrier 70.

The semiconductor device package 7 further includes one or more electronic components 71 and 72 disposed on the surface of the carrier 70. The electronic components 71 and 72 are spaced apart from the semiconductor device package 1. The electronic components 71 and 72 may include active components or a passive component. In some embodiments, the electronic components 71 and 72 may include a resistor, an inductor or a capacitor.

In some embodiments, the carrier 70 may be a printed circuit board (PCB), for example, a rigid PCB, a flexible PCB or a rigid-flex PCB. In some embodiments, a protective coating may be applied to cover the bonding wire w. In some embodiments, the protective coating may be made of an epoxy resin.

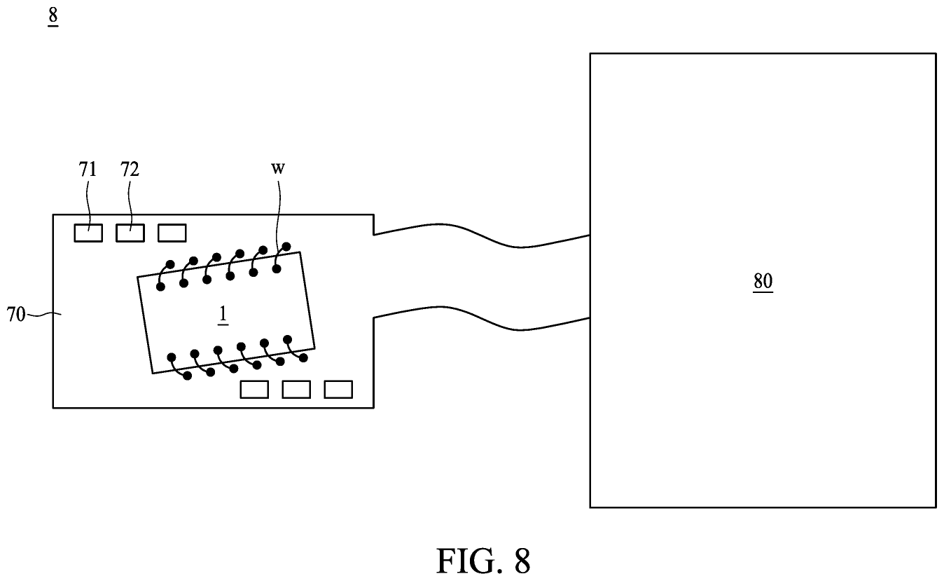

FIG. 8 is a top view of a semiconductor package assembly 8, in accordance with an embodiment of the present disclosure. In some embodiments, the semiconductor device package 7 in FIG. 7 may be a portion of the semiconductor package assembly 8 in FIG. 8.

As shown in FIG. 8, the semiconductor device package 1 is disposed on the carrier 70 and electrically connected to the carrier 70 by the bonding wire w. The semiconductor package assembly further comprises one or more electronic components 71 and 72 disposed on the carrier 70. The carrier 70 may be a rigid-flex PCB. The carrier 70 is electrically connected to a mother board 80.

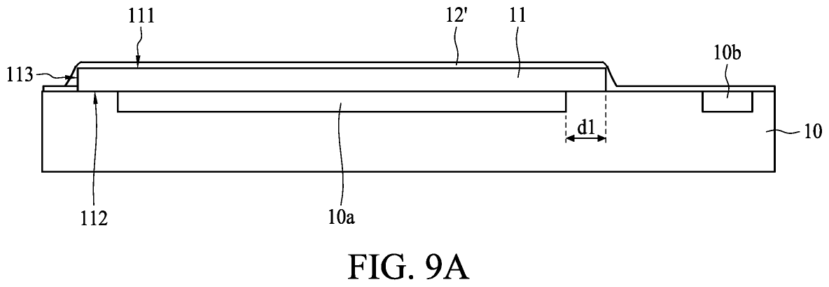

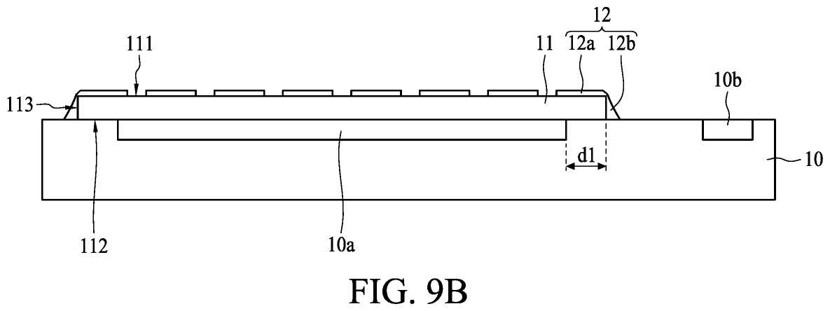

FIG. 9A and FIG. 9B are cross-sectional views of a semiconductor device package at various stages of fabrication, in accordance with some embodiments of the present disclosure. At least some of these figures have been simplified for a better understanding of the aspects of the present disclosure.

Referring to FIG. 9A, a substrate 10 is provided. The substrate 10 includes a sensing region 10a and a bonding region 10b. An optically-sensitive material (such as a photoresist) is applied onto the substrate 10 by spin-coating, spray-coating, or other suitable techniques. Subsequently, the optically-sensitive material is patterned and forms a transparent layer 11 by carrying out an exposure process and a development process. After the exposure process and the development process, a portion of the optically-sensitive material is removed and the bonding region 10b is exposed.

The transparent layer 11 includes a surface 111 facing away from the substrate 10, a surface 112 opposite to the surface 111, and a surface (such as a lateral surface) 113 extending between the surface 111 and the surface 112. The surface 113 may be substantially perpendicular to or angled with the top surface of the underlying substrate 10, depending on the patterning operations.

Afterwards, a light blocking material is applied onto the transparent layer 11 by spin-coating, spray-coating, or other suitable techniques, and followed by a patterning operation (e.g., photolithography techniques). In some embodiments, the light blocking material applied onto the transparent layer 11 may be a carbon black or other light-absorbing material or shading material.

Referring to FIG. 9B, the light blocking material is patterned and forms an opaque layer 12 by carrying out the aforesaid patterning operation. After the patterning operation, a portion of the light blocking material is removed, the bonding region 10b is exposed and the apertures are formed in the opaque layer 12. A portion of the opaque layer 12 is remained on the surface 113 of the transparent layer 11.

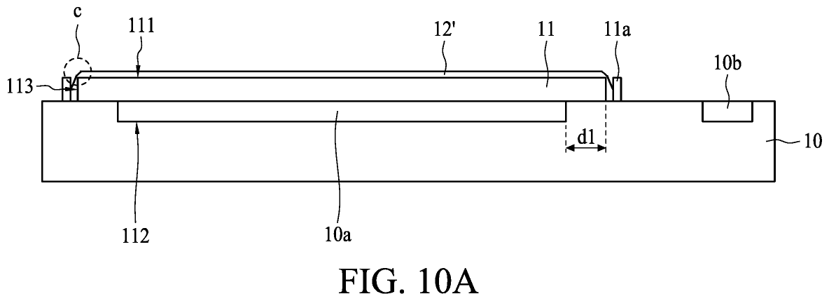

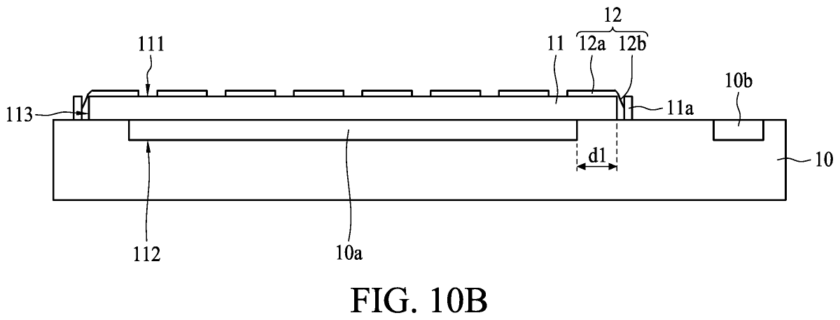

FIG. 10A and FIG. 10B are cross-sectional views of a semiconductor device package at various stages of fabrication, in accordance with some embodiments of the present disclosure. At least some of these figures have been simplified for a better understanding of the aspects of the present disclosure. The stages of fabrication in FIG. 10A and FIG. 10B are similar to the stages of fabrication in FIG. 9A and FIG. 9B, and the differences therebetween are described below.

Referring to FIG. 10A, the optically-sensitive material is patterned and forms a transparent layer 11 and a constraining structure 11a (e.g., a dam structure) during a single lithography operation. Then a light blocking material (e.g., carbon black) is then applied over the transparent layer 11 by spin-coating, spray-coating, or other suitable techniques. Since the light blocking material is constrained by the constraining structure 11a (e.g., a dam structure), the light blocking material will not form the tail portion having a tapered profile as illustrated in FIG. 9B. Compared to the operations described in FIG. 9A, more light blocking material may be left at the corner (which is indicated by the circle “c”) of the transparent layer 11 after a spin coating operation, for example, due the constraint of light blocking material spreading.

Referring to FIG. 10B, the light blocking material is patterned and forms an opaque layer 12 with a plurality of apertures by carrying out a photolithography operation.

Spatially relative terms, such as “beneath,” “below,” “lower,” “above,” “upper,” “left,” “right” and the like, may be used herein for ease of description to describe one element or feature's relationship to another element(s) or feature(s) as illustrated in the figures. The spatially relative terms are intended to encompass different orientations of the device in use or operation, in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately”, “substantially”, “substantial” and “about” are used to describe and account for small variations. When used in conduction with an event or circumstance, the terms can refer to instances in which the event or circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints unless specified otherwise. The term “substantially coplanar” can refer to two surfaces within micrometers (μm) of lying along the same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

What is claimed is:

1. A semiconductor device package, comprising:
a substrate including a sensing region;
a first transparent layer disposed over the sensing region, the first transparent layer having a first surface facing the sensing region, a second surface opposite to the first surface of the first transparent layer, and a lateral surface extending between the first surface and the second surface of the first transparent layer; and
a first light blocking layer disposed on the first transparent layer, the first light blocking layer defining a plurality of apertures;
wherein at least a portion of the first light blocking layer extends over the lateral surface of the first transparent layer.

2. The semiconductor device package as claimed in claim 1, wherein the first light blocking layer is in direct contact with the lateral surface of first transparent layer and a portion of the substrate adjacent to the lateral surface of first transparent layer.

3. The semiconductor device package as claimed in claim 1, wherein the first light blocking layer has a tail extending from the lateral surface of the first transparent layer toward a direction away from the sensing region.

4. The semiconductor device package as claimed in claim 1, wherein the shortest distance between the sensing region and the lateral surface of the first transparent layer is less than about 50 micrometer (μm).

5. The semiconductor device package as claimed in claim 1, further comprising:
a second transparent layer disposed on the first light blocking layer and covers the plurality of apertures.

6. The semiconductor device package as claimed in claim 5, wherein the second transparent layer covers the tail portion of the first light blocking layer

7. The semiconductor device package as claimed in claim 5, further comprising:
a second light blocking layer disposed on the second transparent layer, wherein at least a portion of the second light blocking layer covers a lateral surface of the second transparent layer.

8. The semiconductor device package as claimed in claim 1, further comprising:
a constraining structure disposed on the substrate and spaced apart from the first transparent layer.

9. The semiconductor device package as claimed in claim 8, wherein a part of the first light blocking layer is disposed between the constraining structure and the first transparent layer.

10. A semiconductor device package, comprising:
a micro lens array over a substrate;
a transparent layer surrounding the micro lens array;
a light blocking layer surrounding the transparent layer; and
a bonding region surrounding the light blocking layer.

11. The semiconductor device package as claimed in claim 10, wherein the micro lens array overlaps a sensing region of the substrate supporting the transparent layer and the light blocking layer, the sensing region includes a plurality of light-sensing pixels.

12. The semiconductor device package as claimed in claim 11, wherein a separation between an edge of the sensing region and an edge of the bonding region is in a range of from about 50 μm to about 100 μm.

13. The semiconductor device package as claimed in claim 10, wherein a tail length of the light blocking layer extending from a lateral surface of the transparent layer toward the bonding region is from about 5 μm to about 20 μm.

14. The semiconductor device package as claimed in claim 10, further comprising:
a constraining structure disposed on the substrate and surrounding the transparent layer, wherein the constraining structure is configured to constrain the light blocking layer.

15. A semiconductor package assembly, comprising:
a substrate having an active surface, the substrate including a sensing region and a bonding region disposed adjacent to the active surface or the substrate;
a transparent layer disposed over the sensing region of the first substrate;
an opaque layer disposed on the transparent layer, wherein the opaque layer extends over a lateral surface of the first transparent layer; and
a carrier carrying the substrate, the transparent layer, and the opaque layer, wherein the carrier is electrically connected to the substrate.

16. The semiconductor package assembly as claimed in claim 15, wherein the bonding region of the substrate includes a plurality of conductive pads, each electrically connected to the carrier through a bonding wire.

17. The semiconductor package assembly as claimed in claim 15, wherein a separation between an edge of the sensing region and an edge of the bonding region is in a range of from about 50 μm to about 100 μm.

18. The semiconductor package assembly as claimed in claim 15, wherein the opaque layer comprises a tail portion extending from the lateral surface of the first transparent layer toward the bonding region, the tail portion having a tapering profile.

19. The semiconductor package assembly as claimed in claim 14, further comprising:
a constraining structure between the sensing region and the bonding region, the constraining structure is configured to constrain the opaque layer.

20. The semiconductor package assembly as claimed in claim 14, further comprising:
a passive component disposed on the carrier and spaced apart from the substrate.
